(19) United States
(12) Patent Application Publication
(10) Pub. No.: US 2021/0245006 A1
(43) Pub. Date: Aug. 12, 2021

(54) Apparatus For Use With Exercise Equipment

(71) Applicant: IncludeHealth, Inc., Columbus, OH (US)

(72) Inventor: J. Ryan Eder, Columbus, OH (US)

(21) Appl. No.: 17/168,696

(22) Filed: Feb. 5, 2021

Related U.S. Application Data
(60) Provisional application No. 62/971,578, filed on Feb. 7, 2020.

(51) Int. Cl. A63B 24/00; G01R 1/067

(52) U.S. Cl. CPC A63B 24/0006; A63B 2230/06; A63B 2230/50; G01R 1/06727

(57) ABSTRACT

A system for retaining a sensor that detects motion and communicates with a computer. A receiver mounts to an exercise machine and the sensor mounts in the receiver. The receiver has a sidewall defining a chamber and a movable member opposite the chamber with a tongue extending toward the chamber. A cavity is formed in a first side of the sensor housing and into which the tongue inserts while an opposing, second side of the housing is inserted in the chamber. The chamber sidewall extends from a first side of a panel, and the movable member extends from a second, opposite side of the substantially planar panel. First and second chamber end walls are mounted at opposite ends of the chamber sidewall and may be spaced about a sensor length. The movable member may be a cantilever that is adapted to bend.

### CROSS-REFERENCES TO RELATED APPLICATIONS

This application claims the benefit of U.S. Provisional Application No. 62/971,578 filed Feb. 7, 2020. This prior application is hereby incorporated by reference.

### STATEMENT REGARDING FEDERALLY-SPONSORED RESEARCH AND DEVELOPMENT

(Not Applicable)

### THE NAMES OF THE PARTIES TO A JOINT RESEARCH AGREEMENT

(Not Applicable)

### REFERENCE TO AN APPENDIX

(Not Applicable)

### BACKGROUND OF THE INVENTION

This invention relates to exercise equipment generally, and more particularly to electronic equipment used to sense the movement of exercise equipment and record that movement.

Exercise equipment is used to improve fitness and strength. Many pieces of equipment permit the use of electronic devices to track use, including speed, repetitions, time, and many other parameters. However, because there are so many different manufacturers of exercise equipment, there are many different electronic systems. This makes it difficult for a person to track his or her use of many different pieces of equipment.

For example, treadmills, rowing machines and leg press machines may all permit a person to track his workout. However, if all three machines are from different manufacturers, the data from the workout is unlikely to be recorded in a single software application. Even if a few machines have compatible systems, fitness instructors, physical therapists and athletic trainers may have clients with access to hundreds or thousands of different machines. The probability that all such machines can input data to a single application is low.

Therefore, there is a need for equipment that allows exercise equipment to input data to a single application.

### BRIEF SUMMARY OF THE INVENTION

Disclosed herein is a system for retaining a sensor that detects motion and communicates with at least one computer. The system comprises a receiver adapted for mounting to a movable or stationary component of an exercise machine. The receiver has a chamber sidewall defining a chamber and a movable member opposite the chamber with a tongue extending toward the chamber. The sensor has a housing in which a first side defines a cavity into which the tongue is adapted for insertion while an opposing second side of the housing may be inserted in the chamber. In some embodiments, the chamber sidewall extends from a first side of a substantially planar panel, and the movable member extends from a second, opposite side of the substantially planar panel. In some embodiments, a first chamber end wall is mounted at a first end of the chamber sidewall and a second chamber end wall is mounted at a second, opposite end of the chamber sidewall. The first and second chamber end walls may be spaced about a sensor length. In some embodiments, the movable member further comprises a cantilever that is adapted to bend to permit the movable member to move.

Disclosed herein is a combination sensor and receiver, the combination comprising a housing for the sensor having a first side in which a cavity is formed and a second, opposite side. A chamber sidewall of the receiver is adapted to be mounted to a movable or stationary component of an exercise machine. The chamber sidewall defines a receiver chamber into which the second side of the sensor housing is adapted to be inserted. A movable member on the receiver has a tongue extending toward the chamber that is adapted to insert into the cavity, thereby holding the sensor in the receiver chamber. In some embodiments, the chamber sidewall extends from a first side of a substantially planar panel, and the movable member extends from a second, opposite side of the substantially planar panel. In some embodiments, the combination further comprises a first chamber end wall mounted at a first end of the chamber sidewall and a second chamber end wall mounted at a second, opposite end of the chamber sidewall. The first and second chamber end walls are preferably spaced about a sensor length. In some embodiments, the movable member comprises a cantilever that is adapted to bend to move the movable member.

Disclosed herein is a method of retaining a sensor that detects motion and communicates with at least one computer. The method comprises mounting a receiver to a movable or a stationary component of an exercise machine, the receiver having a chamber sidewall defining a chamber and a movable member opposite the chamber having a tongue extending toward the chamber. The method further comprises disposing a second side of the sensor housing in the chamber. The method further comprises disposing a first side of the sensor housing adjacent the movable member, thereby inserting the tongue into a cavity formed in the first side. In some embodiments, the method further comprises bending the movable member away from the chamber to remove the tongue from the cavity and, thereafter, removing the sensor from the receiver chamber.

### BRIEF DESCRIPTION OF THE SEVERAL VIEWS OF THE DRAWINGS

FIG. 1 is a view in perspective illustrating an embodiment of the invention.

FIG. 2 is a view in perspective illustrating an embodiment of the invention.

FIG. 3 is a view in perspective illustrating an embodiment of the invention.

FIG. 4 is a view in perspective illustrating an embodiment of the receiver.

FIG. 5 is a view in perspective illustrating an embodiment of the receiver.

FIG. 6 is a view in perspective illustrating an embodiment of the invention.

FIG. 7 is a front view in perspective illustrating an embodiment of the sensor.

FIG. 8 is a side view illustrating an embodiment of the receiver.

FIG. 9 is a side view illustrating an embodiment of the invention.

FIG. 10 is a view in perspective illustrating an embodiment of the kiosk base.

FIG. 11 is a view in perspective illustrating an embodiment of the kiosk pedestal and tablet.

FIG. 12 is rear view in perspective illustrating an embodiment of the sensor.

FIG. 13 is a bottom view illustrating the sensor of FIG. 12.

FIG. 14 is a side view illustrating the sensor of FIG. 12.

FIG. 15 is a front view in perspective illustrating an embodiment of the invention.

FIG. 16 is a rear view in perspective illustrating an embodiment of the invention.

FIG. 17 is a front view illustrating an embodiment of the receiver.

FIG. 18 is a front view illustrating an embodiment of the sensor.

In describing the preferred embodiment of the invention which is illustrated in the drawings, specific terminology will be resorted to for the sake of clarity. However, it is not intended that the invention be limited to the specific term so selected and it is to be understood that each specific term includes all technical equivalents which operate in a similar manner to accomplish a similar purpose. For example, the word connected or terms similar thereto are often used. They are not limited to direct connection, but include connection through other elements where such connection is recognized as being equivalent by those skilled in the art.

### DETAILED DESCRIPTION OF THE INVENTION

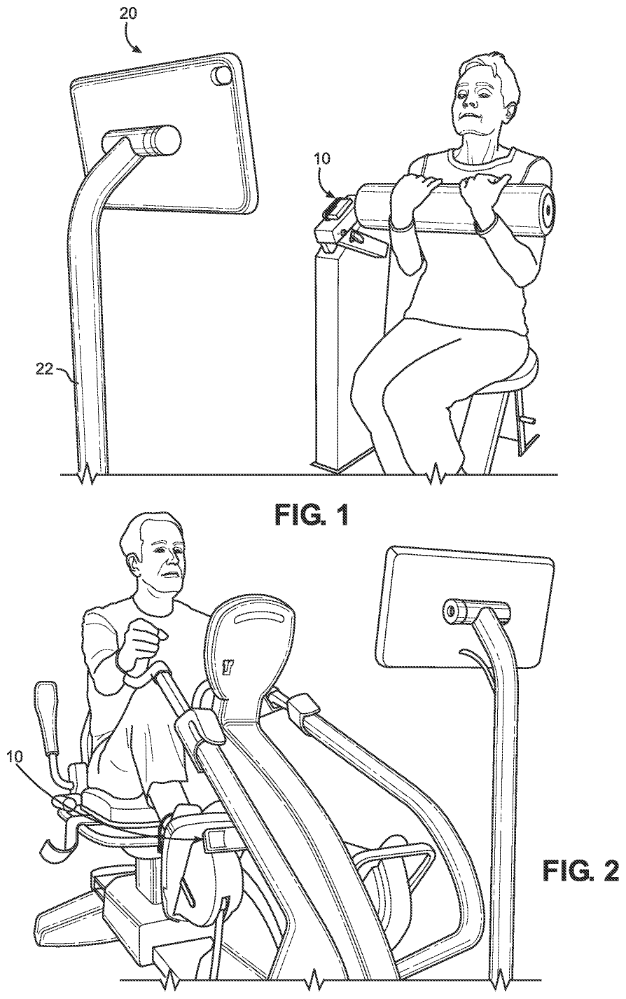

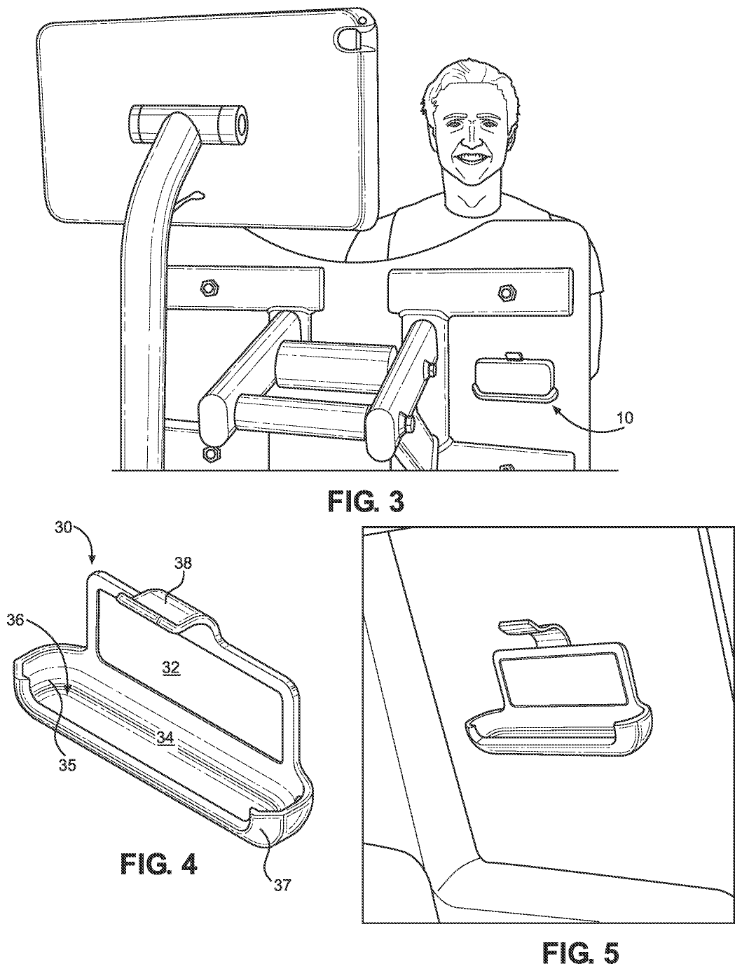

The sensor 10 is an electronic device that may be mounted to a piece of exercise equipment, as shown in FIGS. 1-3, and detects one or more parameters of movement to which the sensor 10 is exposed. For example, the sensor 10 may detect forces applied to the sensor, or acceleration of the sensor 10, such as by an accelerometer housed within the case of the sensor 10. Furthermore, the sensor 10 may detect temperature, humidity, position in space, the speed of movement, and many other parameters. It is contemplated that the sensor 10 may be mounted to a movable component of the machine, and detect the movement of the sensor 10. Alternatively, the sensor 10 may be mounted to a stationary, non-movable portion of the equipment, and detect movement of other components of the equipment, such as by video detection combined with software, vibration of the sensor 10, or other means of detecting movement as will be apparent to the person of ordinary skill.

The sensor 10 preferably includes an outer case 12, which may be hard plastic, glass, aluminum, or any other suitable material that protects the internal electronic components (not visible). The electronic components may include a programmable computer, an accelerometer, a camera, a wireless transceiver, a battery or other power source, and other components that permit the sensor 10 to function as described herein. In a preferred embodiment, the sensor case includes one or more ports for data transmission and battery charging, but wireless charging is also contemplated. The case may be about three inches long, about one and one-half inches wide and about one-half inch thick.

The sensor 10 may form a wired or wireless connection with a central computer, which may be a tablet 20 mounted in close proximity thereto, such as on a pedestal 22 having a base 24 resting on the floor that the piece of exercise equipment rests on. Alternatively, the sensor 10 may wirelessly communicate with a smart phone or any other computer, such as the smart device owned by the user of the exercise equipment.

The combination of the base, pedestal and tablet (computer) may be considered an electronic kiosk, because the combination offers services to the user of the exercise equipment and the manager thereof, as will be described in more detail below. The kiosk may have means 26 for detecting unique identifiers, such as magnetic cards or pendants 27, or alternatively optical scanners, so that a user does not have to enter a user identification and password when he or she begins to use the machine. A wireless transceiver 28 may be mounted to the base or any other portion of the kiosk and communicates wirelessly with the transceiver in the sensor 10 and also communicates with the tablet 20 with a wired or wireless connection.

When the sensor 10 is in an operable position on a piece of equipment, the sensor 10 detects and then transmits data related to conditions and/or movement of the sensor, and therefore of the equipment to which the sensor 10 is mounted. These data are received by the transceiver 28, which then communicates the same to the tablet 20 or other computer. The tablet 20 may display none, some or all of the data, or the tablet 20 may use algorithms pre-programmed into the software thereof to display graphics, which may include numbers, letters, graphs or any other images, to the user. These graphics may communicate to the user of the equipment his or her performance, and are preferably created based on the data transmitted. For example, on a leg press machine, the graphics may communicate to the user how many repetitions she has completed or show the portion of the workout remaining. Furthermore, the data may be communicated, wirelessly or otherwise, to another computer, a network and/or the Internet. Any connection to the Internet is preferably secure and is accessible only by others with authorization. The data may be combined with other data, such as the weight or resistance level, either as entered by the user into the tablet or as programmed on the equipment.

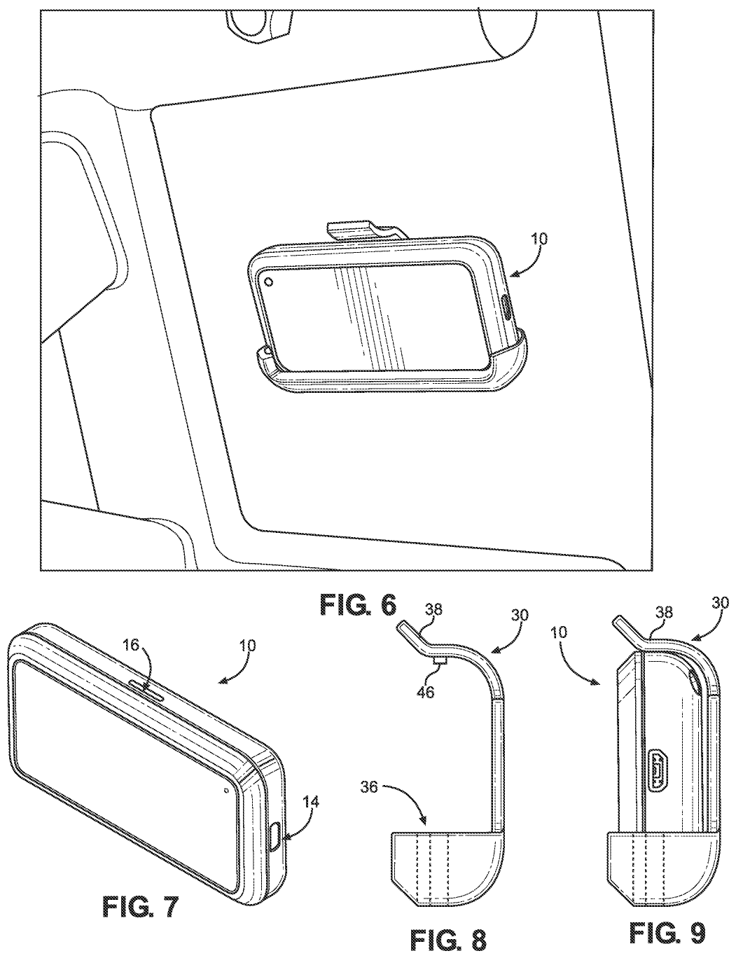

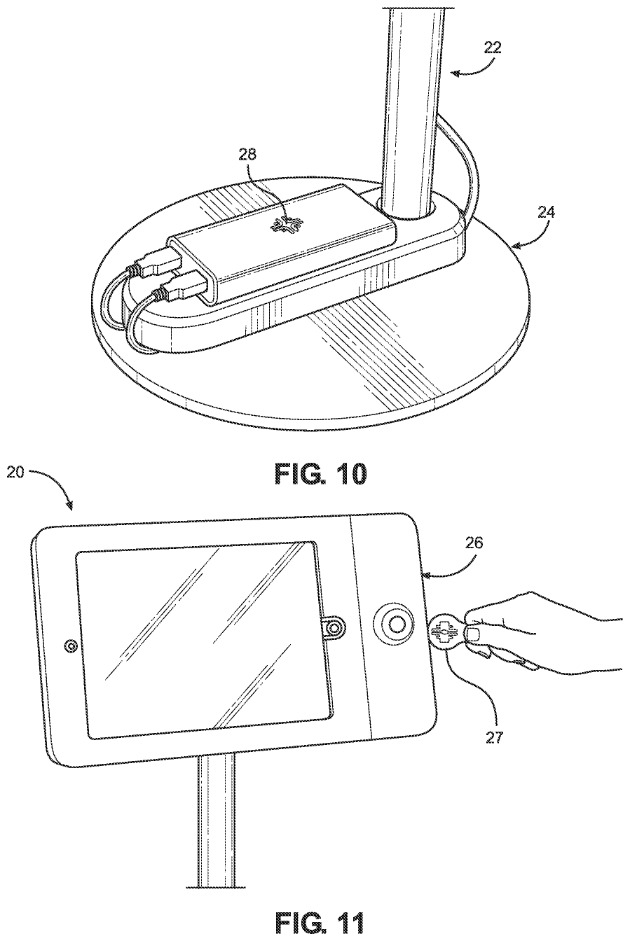

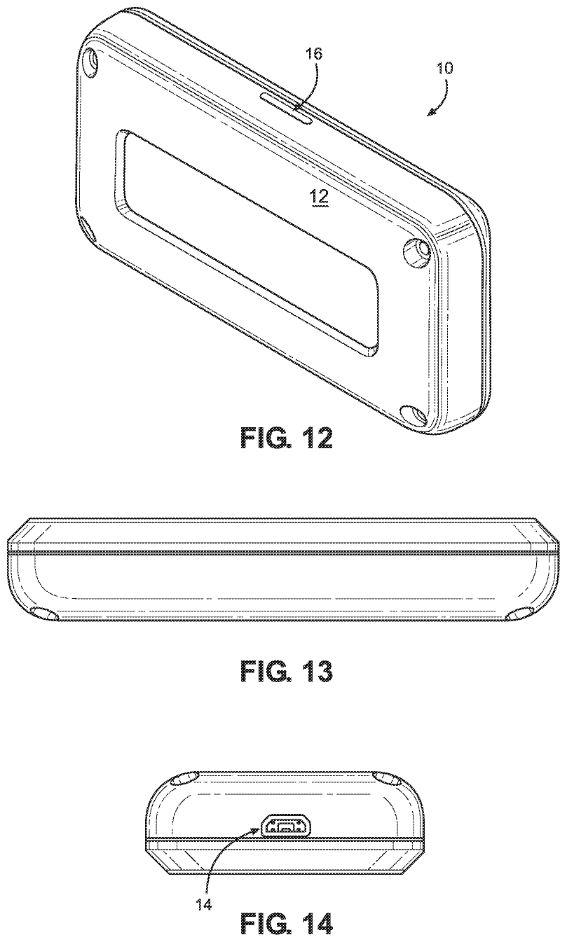

The sensor 10 is shown in detail in FIGS. 6-7 and 12-14 with its case 12 including a data port, which may be a female data port 14 into which a male connector, such as a micro USB connector (not shown), may be inserted to transfer data, charge the power source in the sensor 10 or otherwise function as a control to the electronic components therein. The case 12 also has a cavity 16 formed on the top side of the case 12, in the orientation of FIG. 12. The cavity 16 is substantially centrally located on the side of the case 12, and is preferably elongated in the same direction as the length of the case 12. Preferably, only one side and preferably only one long side, of the case 12 has such a cavity 16. The cavity 16 may be about 2 mm wide, 2 cm long and 3 mm deep, but the size may vary depending on factors such as the spring constant of the structure holding it (described below). The sidewall of the cavity 16 may be curved to form a ramp-like entry and exit to the cavity 16.

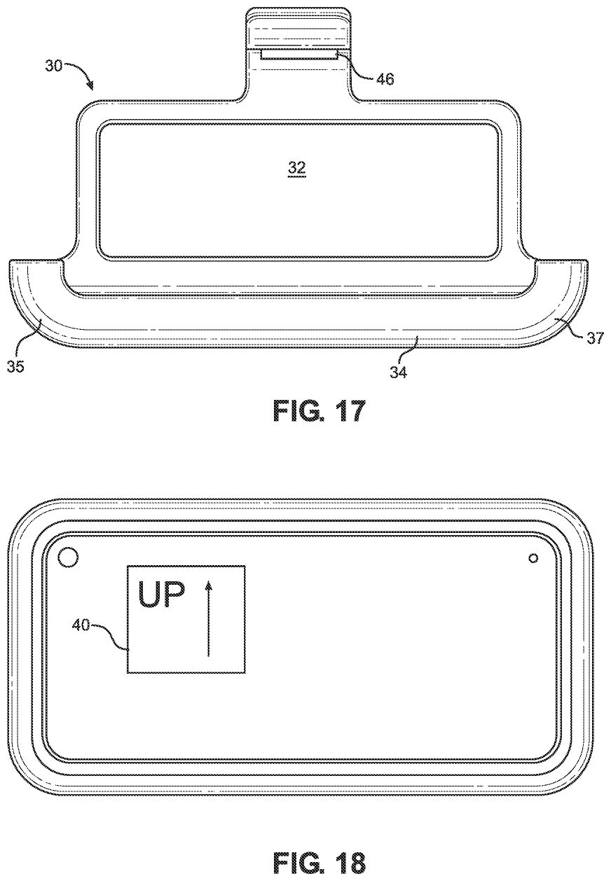

The sensor 10 preferably mounts in a receiver, and one embodiment of a receiver 30 is shown in detail in FIGS. 4-5, 8-9 and 15-17. The receiver 30 has a substantially planar panel 32, from which a curved sidewall 34 extends on its lower side (in the orientation of FIG. 4) to form a chamber 36. A moveable member, such as the clip 38, extends from the opposite side of the planar panel 32 as the sidewall 34, and is integrally attached on the upper side (in the orientation of FIG. 4) to the planar panel 32. End walls 35 and 37 define ends of the chamber 36, and close off the ends of the groove-shaped chamber 36 to prevent the sensor 10 from moving longitudinally too far in the chamber 36.

The chamber 36 receives the lower end (in the orientation of FIG. 4) of the sensor 10. The clip 38 has a tongue 46 facing the chamber 36 that inserts into the cavity 16 on the sensor when the sensor 10 is in an operable position therein, as shown in FIGS. 9 and 15-16. The tongue is about 2-3 mm long to extend sufficiently into, but not farther than, the cavity 16 as described herein. Of course, all of the dimensions may be modified to suit the circumstances. The clip 38 has a spring constant by virtue of being a rigid material, such as plastic, aluminum or fiber-reinforced polymer, and extending from the panel 32 in the manner of a cantilever. Therefore, the clip 38 may flex under pressure applied by a human user, either by applying a force to the clip 38 in a direction having a component parallel to the plane of the panel 32, or by simply pressing the sensor into the receiver 30 as described herein. Pressing the sensor into the receiver moves the clip 38 away from the sensor 10, allowing the clip 38 to snap back when the tongue 46 extends into the cavity 16.

Insertion of the sensor 10 into the receiver is preferably effected (in the orientation of FIG. 7) by inserting the lower end of the receiver 30 into the chamber 36 while leaving the top end of the receiver 30 angled away from the clip 38. The top end of the receiver may be angled about 10-30 degrees relative to the panel 32. Upon further insertion downward of the sensor's lower end into the chamber 36, by pushing the top end closer to the panel 32, the tongue 46 may rise over the top end of the sensor 10 in alignment with the cavity 16 as the angle relative to the panel 32 decreases. Upon the application of sufficient pressure on the sensor 10 toward the panel 32, in optional combination with the application of an upward bending force applied to the clip 38, the tongue 46 begins to insert into the cavity 16. Upon complete insertion of the sensor into the receiver 30, the tongue 46 is precisely located in the cavity 16, and the lower end of the sensor 10 is in the chamber 36 as shown in FIGS. 6, 9 and 15-16.

Because of the complementary shapes and sizes of the case 12 and the void in the receiver 30 that receives the case, when the sensor 10 is completely inserted in the receiver 30, it is in a particular position in space that is precisely located. That is, there is little to no tolerance in the fit between the contacting surfaces of the sensor case 12 and the surfaces of the receiver 30 that define the void to permit the sensor 10 to be in more than one position when completely inserted in the receiver 30. For example, the distance between the end walls 35 and 37 is substantially the distance between the ends of the sensor 10. Likewise, the distance between the top and bottom sides of the sensor case is substantially equal to the distance between the facing surfaces of the clip 38 and the sidewall 34. Thus, the position of the sensor 10 in the receiver 30 during any given insertion is exactly the same as the position of the sensor 10 in the receiver 30 during any other insertion. Therefore, if the sensor 10 is removed for charging, service, security or any other reason, when the sensor 10 is returned to the same receiver 30, its position in space is the same to within fractions of a millimeter relative to its prior position in the same receiver 30.

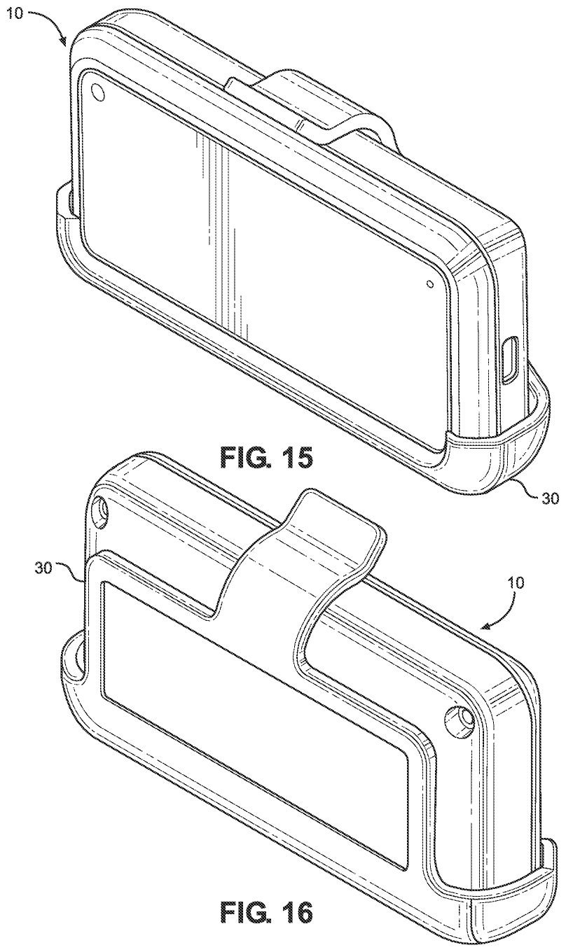

The receiver 30 and sensor 10 may be generally rectangular-shaped, and may have a length that is about twice the width (length being horizontal and width being vertical in FIGS. 15-16). In order to make it clear to the user what orientation each sensor should be inserted in its corresponding receiver, the greater length than width makes this very apparent when the user places the sensor in close proximity to the receiver. Thus, the sensor cannot be inserted in the receiver when rotated 90 degrees in either direction from the correct orientation. However, because it might be difficult to know which side is “up” when inserting the sensor, there is preferably only one cavity 16 on one side edge of the sensor. Thus, if the user tries to insert the sensor 10 into the receiver 30 with the cavity 16 facing downwardly (for example when the receiver 30 is in the orientation of FIG. 8), the tongue 46 has no cavity to insert into, and thus will not retain the sensor in that orientation. This will make it apparent to the user during insertion that the orientation is incorrect. Similarly, if the user attempts to insert the sensor with the cavity side up but with the front of the sensor facing backwards, the tongue 46 will not insert into the cavity due to geometric differences. For example, the cavity 16 may be much closer to the back of the sensor case than the front, or vice versa. Still further, there may be indicia 40 on the front or back of the sensor 10 that is perceptible to the human eye to indicate the correct orientation. Such indicia may be words or symbols that indicate how to orient the sensor correctly. Thus, as the user is determining how to install the sensor, he or she looks at the indicia, inserts the lower end into the chamber and snaps the tongue 46 into the cavity 16. The sensor 10 is then mounted on the equipment to which the receiver 30 is mounted in a location that is included in the software. Therefore, the equipment and sensor need not be calibrated when the sensor is installed in a receiver into which it was previously installed. A rechargeable battery-powered sensor, much like the sensor 10, may be mounted to each exercise or other machine and paired to one or more battery-powered kiosks.

With any machine connected to the computer by a sensor (as described herein) mounted in a receiver (as described herein) thereon, the user can readily create one or more machine sessions on HIPAA-complaint, medical-grade software in the computer. When it is time for a user session, the user may check in using a unique identifier, and open his or her exercise program on the tablet or other computer. The user may be guided by the software through machine setup, exercise instruction, resistance selection and more.

It is contemplated to use customizable, real-time feedback while the user is operating the exercise machine. Furthermore, assessments may provide instant guidance and visibility to performance and progress. In addition, a person who manages the software, such as a physical therapist, may provide real-time heart rate integration and activity-tracking. During each session objective, outcomes-based data may be collected and sent to a remote location for review and analysis. The user and the manager may review a report of each session and/or analyze progress over time. The data may be exported to third-party systems, such as EMRs (Electronic Medical Records). A person managing numerous patients has the ability to expand her capacity for monitoring progress.

An example of a process for using the device includes one or more receivers 30 being mounted to one or more exercise machines, such as a leg press, an abdominal press, a rowing machine, a stationary bicycle, an elliptical trainer, or any other exercise or human-movement machine. The receivers 30 are mounted by adhesive, fasteners or any other means that can firmly fix a receiver 30 to a surface of the machine. In some embodiments, the receivers 30 are fixed to parts of the machines that go through distinct motions so the attached sensor may most effectively measure the movement of those parts of the machine that clearly indicate how the machine is being operated by the user. In some embodiments, the receivers 30 are fixed to parts of the machines that are stationary and the attached sensor measures the movement of other parts of the machine, or the person, using optical sensors, such as cameras.

Once each receiver is in place, a sensor 10 may be installed therein as described above. The user may log in to the computer, such as a tablet that is wirelessly connected to the sensor 10 that is mounted to the first machine the user will use. The user then operates the software of the computer to indicate the sensor being used. This may be by entering data identifying the machine that is being used, because a sensor may be associated with a machine. There may be many ways of indicating which sensor is about to be used, and one way may be for each sensor to have a unique identification that is input to the computer, such as by scanning a bar, QR or other optical code, or otherwise inputting the unique identifier to the computer.

Once the sensor information is in the computer along with information related to the type of machine, the user operates the machine in a normal fashion, such as by pushing against the resistance of a leg press, moving the pedals of a stationary bike, or pulling the bar of a rowing machine. During these movements, the moving sensor 10 moves and records and/or sends that movement information to the computer, or alternatively the stationary sensor 10 detects movement of other objects and records and/or sends that movement information to the computer. The computer may transmit that information to another computer, a network or the Internet, for storage, for use by authorized personnel to analyze the data, or for other legitimate purposes.

Once the user has completed the operation of the particular machine, he or she may remove the sensor, mount it to the receiver of another machine and start the process over again. Removal may be by pulling the clip 38 away from the sensor 10, thereby causing the tongue 46 to be removed from the cavity 16, thereby permitting the sensor to be manually pulled out of the receiver. Alternatively, the sensor may remain on the machine, and when the user moves to a second machine, he or she communicates to a computer the identification of a different sensor on that second machine, and then begins the operation of the second machine. This can continue for many machines until the user has completed his or her workout regimen.

Once the power source, such as replaceable or rechargeable batteries, in a particular sensor is depleted, the sensor may be removed from a respective receiver for battery replacement or charging. Furthermore, a sensor may be removed from a receiver for service, software upgrades or any other reason. Charging may alternatively be accomplished by leaving the sensor in its receiver, if feasible. For example, the port 14 on the sensor 10 of FIG. 6 is accessible while the sensor is in position in the receiver. In such a case, the sensor may be charged or any other connection to the port made while the sensor remains mounted in the receiver.

This detailed description in connection with the drawings is intended principally as a description of the presently preferred embodiments of the invention, and is not intended to represent the only form in which the present invention may be constructed or utilized. The description sets forth the designs, functions, means, and methods of implementing the invention in connection with the illustrated embodiments. It is to be understood, however, that the same or equivalent functions and features may be accomplished by different embodiments that are also intended to be encompassed within the spirit and scope of the invention and that various modifications may be adopted without departing from the invention or scope of the following claims.

1. A system for retaining a sensor that detects motion and communicates with at least one computer, the system comprising a receiver adapted for mounting to a component of an exercise machine, the receiver having a chamber sidewall defining a chamber and a movable member opposite the chamber with a tongue extending toward the chamber, wherein the sensor has a housing in which a first side defines a cavity into which the tongue is adapted for insertion while an opposing, second side of the housing is inserted in the chamber.

2. The system in accordance with claim 1, wherein the chamber sidewall extends from a first side of a substantially planar panel, and the movable member extends from a second, opposite side of the substantially planar panel.

3. The system in accordance with claim 2, further comprising a first chamber end wall mounted at a first end of the chamber sidewall and a second chamber end wall mounted at a second, opposite end of the chamber sidewall, the first and second chamber end walls spaced about a sensor length.

4. The system in accordance with claim 1, wherein the movable member further comprises a cantilever that is adapted to bend to permit the movable member to move.

5. A combination sensor and receiver, the combination comprising:
(a) a housing for the sensor having a first side in which a cavity is formed and a second, opposite side;
(b) a chamber sidewall of the receiver, which is adapted to be mounted to a component of an exercise machine, defining a receiver chamber into which the second side of the sensor housing is adapted to be inserted; and
(c) a movable member on the receiver with a tongue extending toward the chamber and adapted to insert into the cavity, thereby holding the sensor in the receiver chamber.

6. The combination in accordance with claim 5, wherein the chamber sidewall extends from a first side of a substantially planar panel, and the movable member extends from a second, opposite side of the substantially planar panel.

7. The combination in accordance with claim 6, further comprising a first chamber end wall mounted at a first end of the chamber sidewall and a second chamber end wall mounted at a second, opposite end of the chamber sidewall, the first and second chamber end walls spaced about a sensor length.

8. The combination in accordance with claim 5, wherein the movable member further comprises a cantilever that is adapted to bend to move the movable member.

9. A method of retaining a sensor that detects motion and communicates with at least one computer, the method comprising:
(a) mounting a receiver to a component of an exercise machine, the receiver having a chamber sidewall defining a chamber and a movable member opposite the chamber having a tongue extending toward the chamber;
(b) disposing a second side of a sensor housing in the chamber; and
(c) disposing a first side of the sensor housing adjacent the movable member, thereby inserting the tongue into a cavity formed in the first side.

10. The method in accordance with claim 9, further comprising bending the movable member away from the chamber to remove the tongue from the cavity and, thereafter, removing the sensor from the receiver chamber.
